(19) United States
(12) Patent Application Publication
(10) Pub. No.: US 2025/0210382 A1
(43) Pub. Date: Jun. 26, 2025

(54) JIG FOR DISPENSING AN UNDERFILLING MATERIAL

(71) Applicant: Samsung Electronics Co., Ltd., Suwon-si (KR)

(72) Inventors: Junhyeung Jo, Suwon-si (KR); Gyuhyeong Kim, Suwon-si (KR); Jungjoo Kim, Suwon-si (KR); Yongkwan Lee, Suwon-si (KR)

(21) Appl. No.: 18/772,316

(22) Filed: Jul. 15, 2024

(30) Foreign Application Priority Data
Dec. 20, 2023 (KR) 10-2023-0186816

(51) Int. Cl. H01L 21/67; B05C 5/02; B05C 11/10

(52) U.S. Cl. CPC H01L 21/67126; B05C 5/02; B05C 11/1028

(57) ABSTRACT

A jig for dispensing an underfilling material may include a jig body, a dispensing passage and an air passage. The jig body may be configured to cover a package substrate on which a semiconductor chip may be mounted via conductive bumps. The dispensing passage may be formed at one side of the jig body to dispense the underfilling material between the semiconductor chip and the package substrate. The air passage may be extended from the dispensing passage to the other side of the jig body. The jig body may accurately define a dispense region of the underfilling material on an upper surface of the package substrate. Thus, it may not be required to sensitively control a discharge amount of the underfilling material so that a waste of the underfilling material may be reduced. Further, when the underfilling material may make contact with the air passage with closing of the dispensing passage by the cover, the air lock may be formed in the air passage. Thus, a void may not be formed in the underfilling material. Furthermore, an overflow of the underfilling material may be prevented.

### CROSS-RELATED APPLICATION

This application claims priority under 35 USC § 119 to Korean Patent Application No. 10-2023-0186816, filed on Dec. 20, 2023 in the Korean Intellectual Property Office (KIPO), the contents of which are herein incorporated by reference in their entirety.

### BACKGROUND

### 1. Field

Example embodiments relate to a jig for dispensing an underfilling material, and a method of manufacturing a semiconductor device by using the same. More particularly, example embodiments relate to a jig for dispensing an underfilling material to a space between a semiconductor chip and a package substrate.

### 2. Description of the Related Art

Generally, a semiconductor chip may be mounted on a package substrate via conductive bumps. An underfilling material may be dispensed between the semiconductor chip and the package substrate to form an underfilling layer between the conductive bumps.

According to related art, a dam may be formed on an upper surface of the package substrate. The underfilling material may then be dispensed between the dam and the package substrate. However, the underfilling material may not be uniformly dispensed and may form a void in the underfilling layer. Further, the underfilling material may overflow over the dam.

### SUMMARY

Example embodiments provide a jig for dispensing an underfill material that may be capable of preventing a void from being generated and the underfill material from overflowing. Further, example embodiments provide a method of manufacturing a semiconductor device by using a jig for dispensing an underfill material.

According to example embodiments, a jig for dispensing an underfill material includes a jig body, a dispensing passage, a blocker and an air passage. The jig body is configured to cover a substrate on which a mountable electronic component is mounted via bumps. The dispensing passage is configured to dispense the underfilling material to a space between the mountable electronic component and the substrate. The air passage extends from the dispensing passage to another side of the jig body. The air passage is in fluid communication with the dispensing passage.

According to example embodiments, a jig for dispensing an underfill material includes a jig body, a dispensing passage, an air passage and a blocker. The jig body is configured to cover a substrate on which a mountable electronic component is mounted via bumps. The dispensing passage is formed at one side of the jig body to dispense the underfill material to a space between the mountable electronic component and the substrate. The air passage extends from the dispensing passage to another side of the jig body. The blocker is configured to selectively close an upper end of the dispensing passage to form an air lock in the air passage.

According to example embodiments, a jig for dispensing an underfill material includes a jig body and a blocker. The jig body is configured to cover a substrate on which a mountable electronic component is mounted via bumps. The jig body includes an inner passage through which the underfilling material is introduced. The blocker is configured to selectively open and close the inner passage.

According to example embodiments, a method for dispensing an underfill material during manufacturing a semiconductor device includes mounting a mountable electronic component on the substrate via bumps, covering the mountable electronic component and the substrate with a jig body, dispensing the underfill material to a space between the mountable electronic component and the substrate, and providing an air passage extending from the dispensing passage to another side of the jig body. The underfill material is supplied via a dispensing passage formed at one side of the jig body. The air passage is in fluid communication with the dispensing passage.

According to example embodiments, a method for dispensing an underfill material during manufacturing a semiconductor device includes covering a substrate with a jig body the substrate having a mountable electronic component mounted thereon via bumps, dispensing the underfill material to a space between the mountable electronic component and the substrate, and selectively controlling one end of the inner passage to be open or closed. The underfill material is supplied through at least a portion of an inner passage through which the underfill material is introduced.

According to example embodiments, a method for dispensing an underfill material during manufacturing a semiconductor device includes providing a substrate including a first side surface and a second side surface, mounting a mountable electronic component on the substrate through bumps connecting the substrate and the mountable electronic component, providing a passage including a first end, a second end and a third end. The first end is arranged adjacent to the first side surface of the mountable electronic component, and the second end is arranged adjacent to the second side surface of the mountable electronic component. The method for dispensing an underfill material during manufacturing a semiconductor device further includes introducing an amount of an underfill material into the passage through the third end of the passage, introducing an amount of the underfill material from the passage into a space between the bumps, and maintaining a pressure in the passage substantially constant.

According to example embodiments, the jig body may accurately define a dispense region of the underfill material on an upper surface of the package substrate. Thus, it may not be required to sensitively control a discharge amount of the underfill material so that a waste of the underfill material may be reduced. Further, when the underfill material may make contact with the air passage while closing the dispensing passage by the blocker, the air lock may be formed in the air passage. Thus, a void may not be formed in the underfill material. Furthermore, an overflow of the underfill material may be prevented.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a perspective view illustrating a jig for dispensing an underfilling material in accordance with example embodiments.

FIG. 2 is a cross-sectional view illustrating the jig in FIG. 1;

FIGS. 3 to 8 are cross-sectional views illustrating an operation for dispensing an underfilling material using the jig in FIG. 2.

FIG. 9 is a flowchart of a method of manufacturing a semiconductor device according to an embodiment.

FIG. 10 is a flowchart of the method of manufacturing a semiconductor package according to an embodiment.

### DETAILED DESCRIPTION OF THE EMBODIMENTS

Hereinafter, example embodiments will be explained in detail with reference to the accompanying drawings.

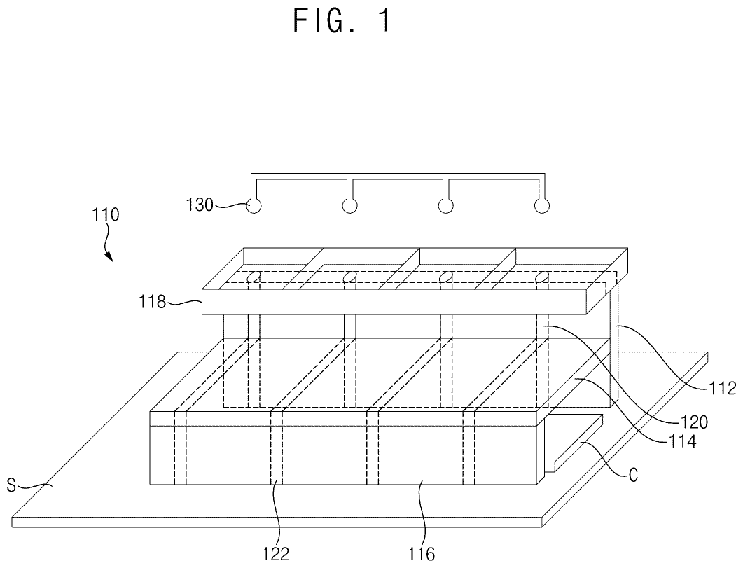

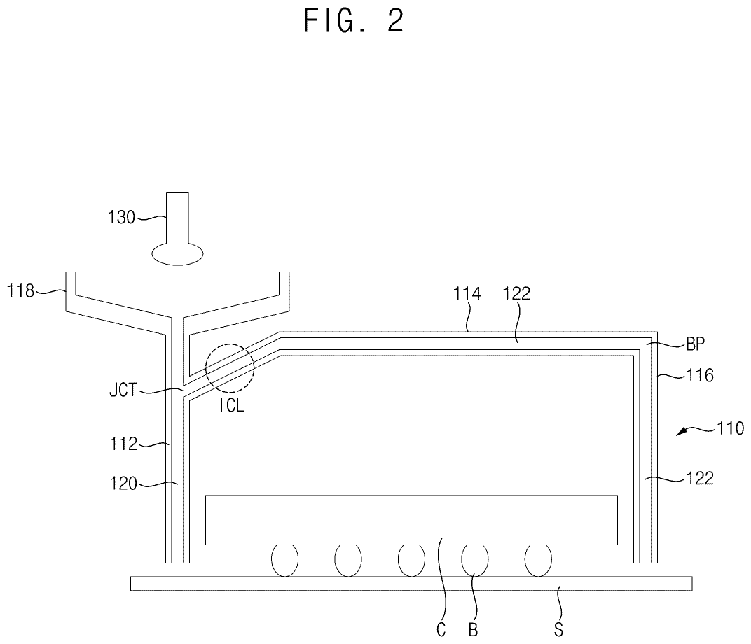

FIG. 1 is a perspective view illustrating a jig for dispensing an underfill material in accordance with example embodiments and FIG. 2 is a cross-sectional view illustrating the jig in FIG. 1.

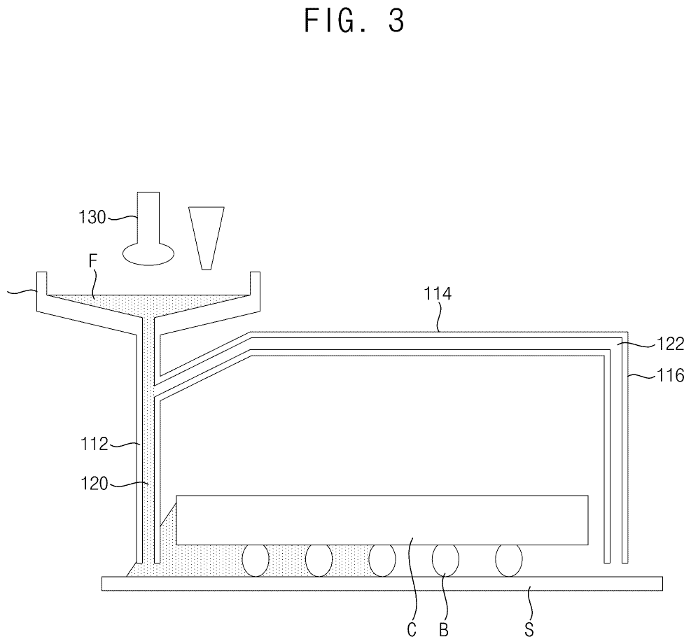

A jig of example embodiments may be used for dispensing an underfill material F (see FIG. 3). Particularly, a semiconductor chip C may be mounted on a package substrate S via conductive bumps B. The conductive bumps B may also be described more generally as a “bump.” Each of the conductive bumps B may be in the form of lands, balls, or pins, and may include a single layer or multiple layers. The semiconductor chip C may be also described more generally as a “mountable electronic component.” The mountable electronic component may include a semiconductor chip (or die), a semiconductor package, an interposer and so on, which may be mounted on a substrate to form a semiconductor device. The package substrate S may be also described more generally as a “substrate”. The substrate may be a package substrate (e.g., a printed circuit board), a semiconductor substrate (e.g., a silicon substrate), an interposer and so on, but is not limited thereto. The jig may be used for dispensing the underfill material F to a space between the semiconductor chip C and the package substrate S.

Referring to FIGS. 1 and 2, the jig of example embodiments may include a jig body 110 and a cover 130.

The jig body 110 may be configured to cover the package substrate S and the semiconductor chip C. For example, the jig body 110 may be arranged on an upper surface of the package substrate S to cover the semiconductor chip C. Thus, the jig body 110 may have a size larger than a size of the semiconductor chip C. Therefore, a space on the upper surface of the package substrate S defined by the jig body 110 may correspond to a dispense region where the underfilling material F (also referred to as “underfill material”) may be dispensed. The jig body 110 may include an inner passage through which the underfilling material F may be introduced. The inner passage may include a dispensing passage 120 and an air passage 122.

In example embodiments, the jig body 110 may include a first side plate 112, an upper plate 114 and a second side plate 116. The first side plate 112 may face the second side plate 116. The upper plate 114 may be connected between an upper end of the first side plate 112 and an upper end of the second side plate 116. The inner passage may be extended in the first side plate 112, the upper plate 114 and the second side plate 116.

The first side plate 112 may be positioned adjacent to a first side surface of the semiconductor chip C. The first side plate 112 may have the upper end positioned higher than the upper surface of the semiconductor chip C. The first side plate 112 may have a lower end positioned adjacent to an upper surface of the package substrate S. For example, the lower end (also may be referred to as “bottom terminal end”) of the first side plate 112 may be spaced apart from the upper surface of the package substrate S to form a gap between the lower end of the first sider plate 112 and the upper surface of the package substrate S.

The dispensing passage 120 may be formed in the first side plate 112, for example, to be formed along the first side plate 112. The dispensing passage 120 may extend from the upper end of the first side plate 112 to the lower end of the first side plate 112. Thus, the underfilling material F may be introduced from an upper end of the dispensing passage 120. The underfilling material F in the dispensing passage 120 may be dispensed to the space between the semiconductor chip C and the package substrate S through a lower end (also referred to as a “first end”) of the dispensing passage 120. Though only one dispensing passage 120 is labeled in FIG. 1, as can be seen, in example embodiments such as depicted in FIG. 1, there may be a plurality of dispensing passages 120. However, the embodiments are not limited thereto.

Additionally, a funnel 118 may be formed at the upper end of the first side plate 112. The underfilling material F may be easily introduced into the upper end of the dispensing passage 120 through the funnel 118.

The upper plate 114 may horizontally extend from the first side plate 112 to cover the package substrate S and the semiconductor chip C. Thus, the upper plate 114 may have an area larger than an area of the package substrate S in a plan view. The air passage 122 may extend in the upper plate 114. The air passage 122 may be connected to the dispensing passage 120 at a junction position JCT. A first length may refer to a length of the dispensing passage 120 from the junction position JCT to the lower end of the dispensing passage 120. The air passage 122 may be in fluid communication with the dispensing passage 120.

The second side plate 116 may face the first side plate 112. The first and second side plate 112 and 116 may extend vertically and be arranged in parallel with each other. The second side plate 116 may be positioned adjacent to a second side surface of the semiconductor chip C. An upper end of the second side plate 116 may be connected to the upper plate 114. The second side plate 116 may have a lower end positioned adjacent to the upper surface of the package substrate S. For example, the lower end of the second side plate 116 may be spaced apart from the upper surface of the package substrate S to form a gap between the lower end of the second side plate 116 and the upper surface of the package substrate S.

The air passage 122 may extend in the second side plate 116. For example, the air passage 122 may extend from the upper end of the second side plate 116 to the lower end of the second side plate 116. At the upper end of the second side plate 116, a horizontal portion of the air passage 122 may be connected to a vertical part of the air passage 122 at a position BP.

The horizontal portion may extend in parallel to the upper surface of the substrate S. Accordingly, the air passage 122 may extend in the upper plate 114 from the dispensing passage 120 to the lower end of the second side plate 116. A second length may refer to a length of the air passage 122 from the junction position JCT to the lower end of the air passage 122 at the second side plate 116. The second length may be greater than the first length described previously. The air passage 122 may have an inclined portion ICL. The inclined portion ICL may be inclined with respect to the upper surface of the substrate S. The inclined portion ICL may be connected to the junction position JCT. The inclined portion ICL may be connected to the horizontal portion of the air passage 122. The position BP may be arranged at a location higher than the position JCT with respect to the upper surface of the substrate S and in a direction perpendicular to the upper surface of the substrate S, where locations further from the substrate in the direction perpendicular to the substrate are higher than locations closer to the substrate. For example, the horizontal portion may be arranged at a location higher than the junction position JCT with respect to the upper surface of the substrate S in a direction perpendicular to the upper surface of the substrate S.

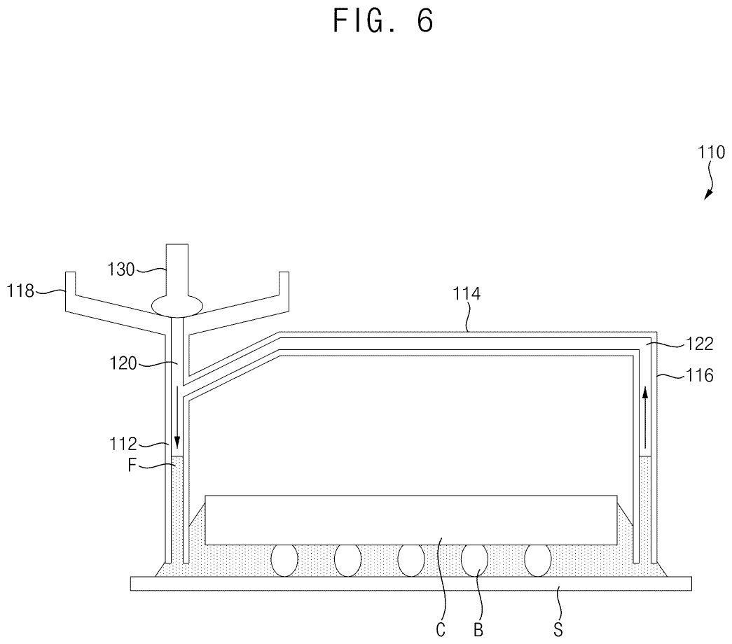

A portion of the underfilling material F, which may be dispensed from the lower end of the dispensing passage 120, may be introduced into the air passage 122 through a lower end (also referred to as a “second end”) of the air passage 122 as depicted in FIG. 6. When a plurality of dispensing passages 120 are included, a plurality of respective passages 122 may also be included. For example, in example embodiments, a plurality of air passages 122 may be connected to a corresponding plurality of respective dispensing passages 120.

The cover 130 (also described as a “blocker” or a “liftable blocker”) may be arranged over the first side plate 112 in a liftable (or movable) manner to selectively open and close the upper end of the dispensing passage 120. Thus, the cover 130 may have a shape configured to fully close the upper end of the dispensing passage 120. For example, when the upper end of the dispensing passage 120 has a circular shape, the cover 130 may have a spherical shape having a diameter longer than a diameter of the dispensing passage 120. The cover 130 may be lifted by an actuator. When a plurality of dispensing passages 120 are included, a plurality of the covers 130 may simultaneously open and close the upper ends of the dispensing passages 120. The plurality of covers may be, for example, a plurality of plugs or stoppers.

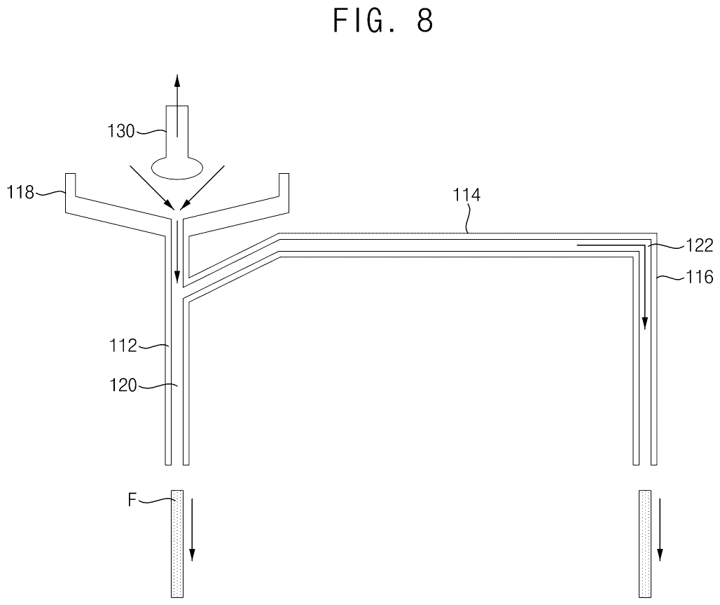

When the cover 130 closes the upper end of the dispensing passage 120, air may not be supplied to the dispensing passage 120 and the air passage 122 from the funnel 118, or may be substantially blocked from being supplied to the dispensing passage 120 and the air passage 122 from the funnel 118. Further, when the portion of the underfilling material F exists in the dispensing passage 120 and the air passage 122, the air may be prevented or substantially prevented from being introduced into the dispensing passage 120 and the air passage 122 as depicted in FIG. 6. Thus, a pressure in the dispensing passage 120 and the air passage 122 may be substantially constantly maintained to generate an air lock in the dispensing passage 120 and the air passage 122 as described later. In contrast, when the cover 130 may open the upper end of the dispensing passage 120, the air lock may be released. Thus, the underfilling material F in the dispensing passage 120 and the air passage 122 may be discharged from the dispensing passage 120 and the air passage 122 as depicted in FIG. 8. In example embodiments, the cover 130 may include or be formed of a resilient material such as a rubber, but not limited thereto.

FIGS. 3 to 8 are cross-sectional views illustrating an operation for dispensing an underfilling material using the jig in FIG. 2, and a method of manufacturing a semiconductor device by using the jig.

Referring to FIG. 3, the method of manufacturing a semiconductor device may include mounting a semiconductor chip C on a package substrate S. The jig described in FIG. 2 may be provided on the semiconductor chip C. The underfill material F may be introduced into the dispensing passage 120, while the cover 130 is positioned so the upper end of the dispensing passage 120 is open. The underfill material F may be dispensed to the space between the semiconductor chip C and the package substrate S through the lower end of the dispensing passage 120. The underfill material F may be introduced onto the substrate adjacent to the first side surface of the semiconductor chip C. The space between the semiconductor chip C and the package substrate S may be filled with the underfill material F. The underfill material F may be absorbed underneath the semiconductor chip via capillary action. In an embodiment, the lower end of the dispensing passage 120 may be configured to direct the underfill material F toward the space between the semiconductor chip C and the package substrate S. For example, lower end of the dispensing passage 120 may be bent toward the space between the semiconductor chip C and the package substrate S.

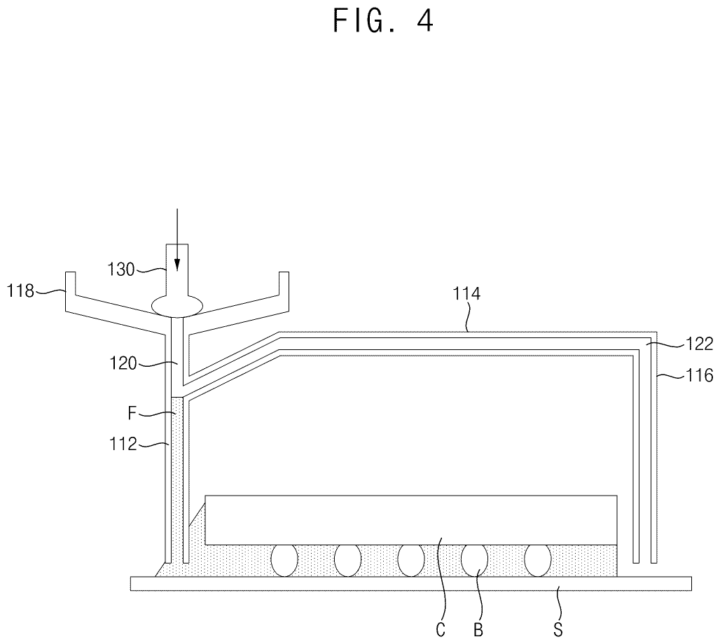

Referring to FIG. 4, the underfilling material F may be continuously introduced into the dispensing passage 120 until the space between the semiconductor chip C and the package substrate S is fully filled with the underfill material F. When the space between the semiconductor chip C and the package substrate S is fully filled with the underfill material F, the cover 130 may block (i.e., close) the upper end (also referred to as a “third end”) of the dispensing passage 120. In an embodiment, the cover 130 may block the upper end of the dispensing passage 120 before the space between the semiconductor chip C and the package substrate S is fully filled with the underfill material F.

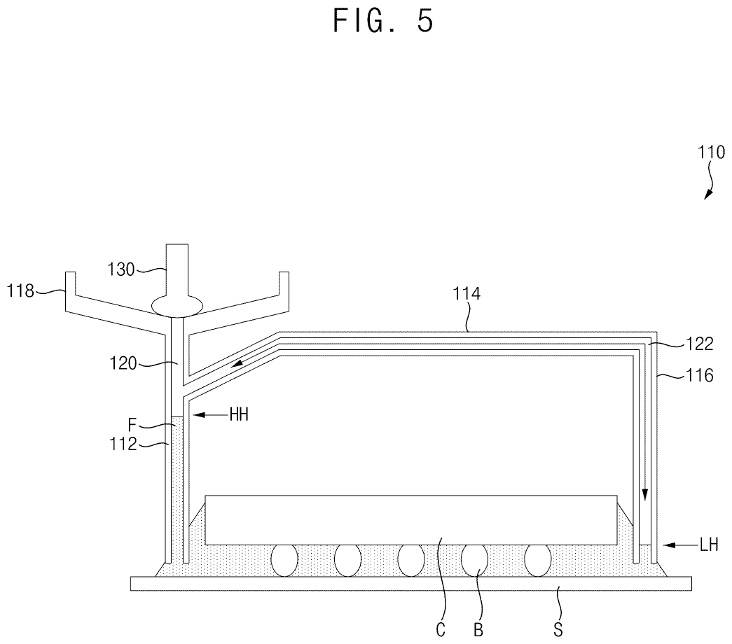

Referring to FIG. 5, a portion of the underfilling material F may remain in the dispensing passage 120. Further, a portion of the underfilling material F may overflow beyond the second side surface of the package substrate S, and the portion of the underfilling material F may enter into the air passage 122 through the lower end of the air passage 122. In an embodiment, the cover 130 may block the upper end of the dispensing passage 120 simultaneously with the occurrence of the overflow.

When the cover 130 closes the upper end of the dispensing passage 120, a portion of the underfilling material F may remain in the dispensing passage 120 and the air passage 122. For example, the underfill material F in the dispensing passage 120 may have an upper height level HH higher than an upper height level LH of the underfilling material F in the air passage 122. Because the cover 130 and the portion of the underfilling material F block all of the inlet and outlet of the inner passage, the air may substantially not be introduced into the inner passage, thereby generating the air lock in the dispensing passage 120 and the air passage 122.

Referring to FIG. 6, when the air lock is generated, the dispensing passage 120 and the air passage 122 may have the same inner pressure. The upper height level HH of the underfilling material F in the dispensing passage 120 may be lowered and the upper height level LH of the underfilling material F in the air passage 122 may be heightened. As a result, the underfill material F in the dispensing passage 120 may have substantially the same height level in both the dispensing passage 120 and the air passage 122. Further, the underfill material F may not be supplied any more onto the substrate S from the dispensing passage 120.

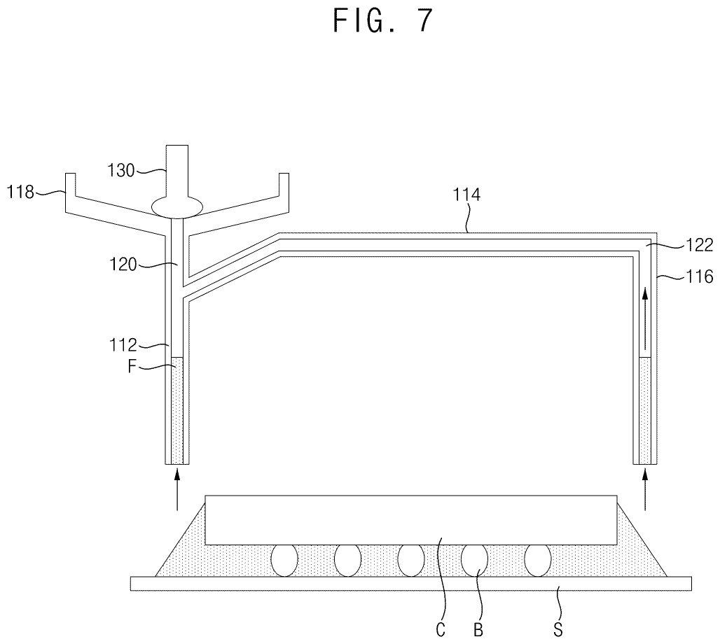

Referring to FIG. 7, the jig may be upwardly moved to separate the jig from the package substrate S. Because the cover 130 may continuously block the upper end of the dispensing passage 120, the air lock in the dispensing passage 120 and the air passage 122 may be continuously maintained.

Referring to FIG. 8, the cover 130 may be upwardly moved to open the upper end of the dispensing passage 120. The air may be introduced into the inner passage to release the air lock. Thus, the underfilling material F in the dispensing passage 120 and the air passage 122 may be discharged through the lower ends of the dispensing passage 120 and the air passage 122.

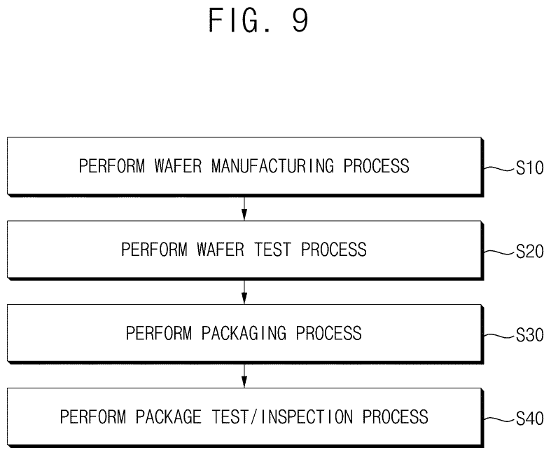

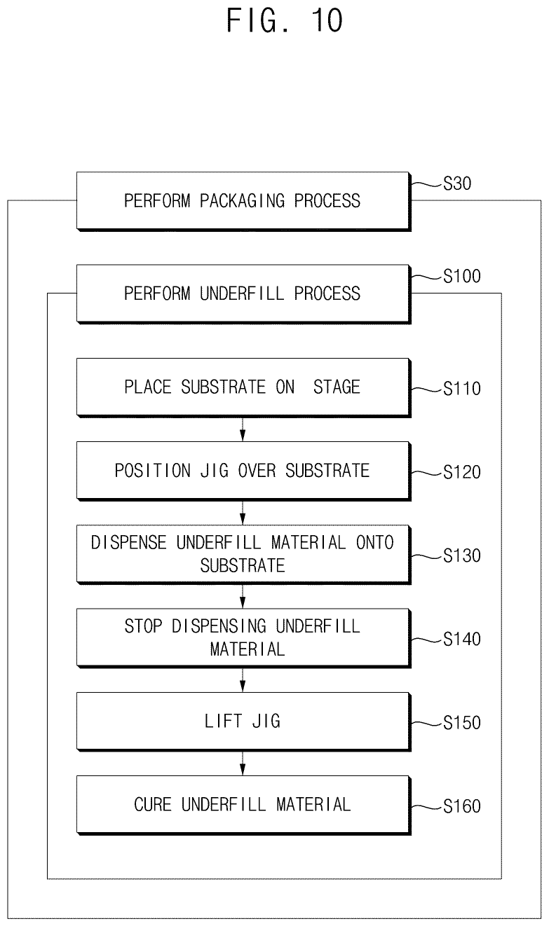

FIG. 9 is a flowchart of a method of manufacturing a semiconductor device according to an embodiment. FIG. 10 is a flowchart of the method of manufacturing a semiconductor package according to an embodiment.

Referring to FIG. 9, an operation S10 of performing wafer manufacturing process may be performed to provide a semiconductor wafer on which a plurality of semiconductor chips (i.e., the semiconductor chip C In FIG. 1) are formed. One or more manufacturing processes may be performed. For example, an oxidation process, a photolithography process, a deposition process, an etching process, an ion process, and/or a cleaning process may be performed on the semiconductor wafer.

Subsequently, an operation S20 of performing wafer test process may be performed to classify individual chips on a wafer level. For example, the operation S20 may be an electrical die sorting (EDS) process, which may test electrical characteristics of the plurality of semiconductor chips.

Subsequently, an operation S30 of performing packaging process may be performed to provide a semiconductor package including one or more chips which are classified to be subject to subsequent packaging process steps described herein. For example, the operation S30 may include sawing the wafer and obtaining the individual semiconductor chips, attaching (i.e. mounting) the individual chips on a substrate (e.g., substrate S In FIG. 1), molding the individual chips, etc.

Referring to FIG. 10, the operation S30 may include an operation S100 of performing underfill process. The operation S100 may include an operation S110 of placing substrate on a stage, an operation S120 of position jig over substrate, an operation S130 of dispensing underfill material onto substrate, an operation S140 of stopping dispensing the underfill material and operation S150 of lifting jig. The operations S120, S130, S120, S140 and S150 may be performed as described with FIGS. 1 to 9 previously. Accordingly, repeated descriptions may be omitted.

In an embodiment, a method for dispensing an underfill material F during manufacturing a semiconductor device may include mounting a mountable electronic component (i.e. semiconductor chips C) on the substrate S via bumps B. A jig body 110 may cover the mountable electronic component C and the substrate S with a jig body 110. Dispensing the underfill material F may be performed to a space between the mountable electronic component C and the substrate S. The underfill material F may be supplied via a dispensing passage 120 that is arranged at one side of the jig body 110. An air passage 122 may be provided. The air passage 122 may extend from the dispensing passage 120 to another side of the jig body 110. The air passage 122 may be in fluid communication with the dispensing passage 120.

During the dispensing, a first side plate 112 of the jig body 110 may be positioned adjacent to one side surface of the mountable electronic component C, an upper plate 114 of the jig body 110 may extend from the first side plate 112 of the jig body 110 and covers the mountable electronic component C, and a second side plate 116 of the jig body 110 may extend from the upper plate 114 of the jig body 110 and may be positioned adjacent to the other side surface of the mountable electronic component C.

During the dispensing, a lower end of the second side plate 116 of the jig body 110 may be spaced apart from an upper surface of the substrate S, and the air passage 122 may extend from the dispensing passage 120 to the lower end of the second side plate 116 of the jig body 110 through the upper plate 114 of the jig body 110.

The air passage 122 may be connected to the dispensing passage 120 at a junction position JCT. A first length of the dispensing passage 120 from the junction position JCT to the lower end of the dispensing passage 120 may be less than a second length of the air passage 122 from the junction position to the lower end of the air passage 122. The air passage 122 may have an inclined portion ICL and a horizontal portion. The inclined portion ICL of the air passage 122 may be inclined with respect to the upper surface of the substrate S. The horizontal portion of the air passage 122 may extend in parallel to the upper surface of the substrate S. The inclined portion ICL of the air passage 122 may be connected to the horizontal portion of the air passage 122. The horizontal portion may be arranged at a location higher than the junction position JCT with respect to the upper surface of the substrate S in a direction perpendicular to the upper surface of the substrate S.

An upper end of the dispensing passage 120 may be configured to be selectively controlled to be opened or closed. A funnel 118 may be provided and that may be arranged at the upper end of the first side plate 112 of the jig body 110. The funnel 118 may be in fluid communication with the dispensing passage 120. A lower end of the first side plate 112 of the jig body 110 may be spaced apart from an upper surface of the substrate S. The upper end of the dispensing passage 120 may be selectively controlled by closing or opening the funnel by a blocker 130.

In an embodiment, a method for dispensing an underfill material F during manufacturing a semiconductor device may include covering a substrate S with a jig body 110. The substrate S may have a mountable electronic component C mounted thereon via bumps B. The underfill material F may be dispensed to a space between the mountable electronic component C and the substrate S. The underfill material F may be supplied through at least a portion of an inner passage through which the underfill material F is introduced. One end of the inner passage may be selectively controlled to be open or closed by blocker 130.

The inner passage may include a dispensing passage 120 and an air passage 122. The air passage 122 may be in fluid communication with the dispensing passage 120. The underfill material F may be supplied to the space between the mountable electronic component C and the substrate S though the dispensing passage 120. During the dispensing the underfill material F, the underfill material F may be supplied through the dispensing passage 120. An amount of the underfill material F may be introduced into the air passage 122. The amount of the underfill material F may be introduced into the air passage 122 through a lower end of the air passage 122.

The selectively controlling may include closing of an upper end of the dispensing passage 120, thereby maintaining substantially constant pressure within the dispensing passage 12 and the air passage 122. For example, a pressure in the dispensing passage 120 and the air passage 122 may be maintained substantially constant by closing the upper end of the dispensing passage 120. The lower end of dispensing passage 120 may be spaced apart from an upper surface of the substrate S during the dispensing. By the maintaining the pressure in the dispensing passage 120 and the air passage 122 substantially constant, the supplying of the underfill material F through the dispensing passage 120 may be cut off. The selectively controlling may be performed by a blocker 130 configured to selectively open or close an upper end of the dispensing passage 120.

In an embodiment, a method of manufacturing a semiconductor device may include providing a substrate S including a first side surface and a second side surface. A mountable electronic component C may be mounted on the substrate S through bumps B. The bumps B may connect the substrate S and the mountable electronic component C. A passage may include a first end, a second end and a third end. The first end may be arranged adjacent to the first side surface of the mountable electronic component C. The second end may be arranged adjacent to the second side surface of the mountable electronic component C.

An amount of an underfill material F may be introduced into the passage through the third end of the passage. An amount of the underfill material F may be introduced from the passage into a space between the bumps B. A pressure within the passage may be maintained substantially constant. During the introducing of an amount of the underfill material F into the passage through the second end of the passage, the first end of the passage may be maintained to be closed.

The passage may include a dispensing passage 120 and an air passage 122. The first end of passage may be an upper end of the dispensing passage 120. The second end of passage may be a lower end of the dispensing passage 120. The third end of passage may be a lower end of the air passage 122. The upper end of the dispensing passage 120 may be closed before the space between the mountable electronic component C and the substrate S is fully filled with underfill material F. The underfill material F may overflow the space between the mountable electronic component C and the substrate S, after the space between the mountable electronic component C and the substrate S is fully filled with the underfill material F. The upper end of the dispensing passage 120 may be closed simultaneously with the occurrence of the overflow. When the upper end of the dispensing passage 120 is closed, a portion of the underfill material F may remain in the dispensing passage 120 and the air passage 122. When the upper end of the dispensing passage 120 is closed, the underfill material F in the dispensing passage 120 may have an upper height level higher than an upper height level of the underfill material F in the air passage 122.

After the upper end of the dispensing passage 120 is closed, the upper height level of the underfill material F in the dispensing passage 120 may be lowered, and the upper height level of the underfill material F in the air passage 122 may be heightened. The lowered upper height level of the underfill material F in the dispensing passage 120 may be substantially the same as the heightened upper height level of the underfill material F in the air passage 122.

In an operation S160 of curing underfill material, the portion of the underfill material F, which remains on the substrate S may be subjected to a curing process. By undergoing the curing process, the underfill material F may have more strengthened stiffness. After the underfilling process above, subsequent packaging processes (e.g., a molding process, a wire bonding process, and so on) may be performed to complete the method of manufacturing a semiconductor package.

Subsequently, an operation S40 of performing package test/inspection process in FIG. 9 may be performed. For example, the semiconductor package may be tested to verify an electrical operation of the semiconductor package. Further, an inspection may be performed on a package manufactured by the packaging process.

In example embodiments, the jig body 110 may include the two side plates 112 and 116 and the upper plate 114, but not limited thereto. For example, the jig body 110 may have various other shapes with the dispensing passage 120 and the 130 122 configured to cover the package substrate S and the semiconductor chip C.

According to example embodiments, the jig body may accurately define a dispense region of the underfilling material on an upper surface of the package substrate. Thus, it may not be required to sensitively control the discharge amount of the underfilling material so that a waste of the underfilling material may be reduced. Further, when the underfilling material makes contact with the air passage with closing of the dispensing passage by the cover, the air lock may be formed in the air passage. Thus, a void may not be formed in the underfilling material. Furthermore, an overflow of the underfilling material may be prevented.

The foregoing is illustrative of example embodiments and is not to be construed as limiting thereof. Although a few example embodiments have been described, those skilled in the art will readily appreciate that many modifications are possible in the example embodiments without droplet departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

1. A jig for dispensing an underfill material, the jig comprising:
a jig body configured to cover a substrate on which a mountable electronic component is mounted via bumps;
a dispensing passage formed at one side of the jig body configured to dispense the underfill material to a space between the mountable electronic component and the substrate; and
an air passage extending from the dispensing passage to another side of the jig body, wherein the air passage is in fluid communication with the dispensing passage.

2. The jig of claim 1, wherein the jig body comprises:
a first side plate positioned adjacent to one side surface of the mountable electronic component;
an upper plate extending from the first side plate to cover the mountable electronic component; and
a second side plate extending from the upper plate and positioned adjacent to another side surface of the mountable electronic component.

3. The jig of claim 2, wherein the first side plate has a lower end spaced apart from an upper surface of the substrate.

4. The jig of claim 3, wherein the dispensing passage extends from an upper end of the first side plate to the lower end of the first side plate.

5. The jig of claim 4, wherein the jig body further comprises a funnel formed at the upper end of the first side plate.

6. The jig of claim 4, further comprising a blocker configured to selectively open and close an upper end of the dispensing passage.

7. The jig of claim 2, wherein the second side plate has a lower end spaced apart from an upper surface of the substrate.

8. The jig of claim 7, wherein the air passage extends from the dispensing passage to the lower end of the second side plate through the upper plate.

9. A jig for dispensing an underfill material, the jig comprising:
a jig body configured to cover a substrate on which a mountable electronic component is mounted via bumps;
a dispensing passage formed at one side of the jig body to dispense the underfill material to a space between the mountable electronic component and the substrate;
an air passage extending from the dispensing passage to another side of the jig body; and
a blocker configured to selectively close an upper end of the dispensing passage to form an air lock in the air passage.

10. The jig of claim 9, wherein the jig body comprises:
a first side plate positioned adjacent to one side surface of the mountable electronic component;
an upper plate extending from the first side plate to cover the mountable electronic component; and
a second side plate extending from the upper plate and positioned adjacent to another side surface of the mountable electronic component.

11. The jig of claim 10, wherein the first side plate has a lower end spaced apart from an upper surface of the substrate.

12. The jig of claim 11, wherein the dispensing passage extends from an upper end of the first side plate to the lower end of the first side plate.

13. The jig of claim 12, wherein the jig body further comprises a funnel formed at the upper end of the first side plate.

14. The jig of claim 10, wherein the second side plate has a lower end spaced apart from an upper surface of the substrate.

15. The jig of claim 14, wherein the air passage extends from the dispensing passage to the lower end of the second side plate through the upper plate.

16. A jig for dispensing an underfill material, the jig comprising:
a jig body configured to cover a substrate on which a mountable electronic component is mounted via bumps, the jig body including an inner passage through which the underfill material is introduced; and
a blocker configured to selectively open and close the inner passage.

17. The jig of claim 16, wherein the jig body comprises:
a first side plate positioned adjacent to one side surface of the mountable electronic component;
an upper plate extended from the first side plate to cover the mountable electronic component; and
a second side plate extended from the upper plate and positioned adjacent to another side surface of the mountable electronic component.

18. The jig of claim 17, wherein the inner passage comprises:
a dispensing passage extended from an upper end of the first side plate to a lower end of the first side plate to dispense the underfill material to a space between the mountable electronic component and the substrate; and
an air passage extended from the dispensing passage to a lower end of the second side plate through the upper plate.

19. The jig of claim 18, wherein the lower end of the first side plate spaced apart from an upper surface of the substrate, and the lower end of the second side plate spaced apart from the upper surface of the substrate.

20. The jig of claim 18, wherein the jig body further comprises a funnel formed at the upper end of the first side plate.

21-40. (canceled)
